(19) United States
(12) Patent Application Publication
(10) Pub. No.: US 2026/0033401 A1
(43) Pub. Date: Jan. 29, 2026

(54) Power Module

(71) Applicants: HYUNDAI MOTOR COMPANY, Seoul (KR); KIA CORPORATION, Seoul (KR)

(72) Inventors: Jun Hee Park, Hwaseong-si (KR); Se Yoon Jeong, Hwaseong-si (KR); Se Bin Kim, Hwaseong-si (KR); Nam Sik Kong, Hwaseong-si (KR); Sung Taek Hwang, Hwaseong-si (KR)

(73) Assignees: HYUNDAI MOTOR COMPANY, Seoul (KR); KIA CORPORATION, Seoul (KR)

(21) Appl. No.: 18/967,619

(22) Filed: Dec. 3, 2024

(30) Foreign Application Priority Data
Jul. 29, 2024 (KR) 10-2024-0100347
Oct. 30, 2024 (KR) 10-2024-0151411

(51) Int. Cl. H01L 23/498; H01L 23/00

(52) U.S. Cl. CPC H01L 23/49833; H01L 23/49811; H01L 23/49861; H01L 24/32; H01L 2224/26152; H01L 2224/32238

(57) ABSTRACT

According to the present disclosure, upper and lower substrates may be electrically connected to a lead frame, such that wire bonding may be excluded, and electrical connection and heat dissipation may be performed without a spacer by improving a connection structure in the upper and lower substrates. In addition, a power module is introduced in which because a spacer for forming a large current path may be excluded, a current path may be shortened, such that power performance may be improved, an internal space may be additionally provided, costs may be reduced, and an overall size of the power module may be reduced.

### CROSS-REFERENCE TO RELATED APPLICATIONS

The present application claims priority to Korean Patent Application No. 10-2024-0100347, filed on Jul. 29, 2024, and Korean Patent Application No. 10-2024-0151411, filed on Oct. 30, 2024, the entire contents of which are incorporated herein for all purposes by this reference.

### TECHNICAL FIELD

The present disclosure relates to a power module in which a connection structure between an upper substrate and a lower substrate is improved to improve power performance and cooling performance.

### BACKGROUND

Recently, as there is increasing interest in environment, the number of environmental-friendly vehicles using electric motors as power sources increases. The environmental-friendly vehicle is called a motorized vehicle. The representative examples of the environmental-friendly vehicles include an electric vehicle (EV) and a hybrid electric vehicle (HEV).

The motorized vehicle is equipped with an inverter configured to convert direct current power into alternating current power when the motor operates. The inverter generally includes one or a plurality of power modules having a semiconductor chip configured to perform a switching function.

In general, a pattern is formed on a surface of a substrate in the power module, and the power module is connected to a signal lead by wire bonding or the like, such that the power module may perform signal connection with the outside. In addition, a spacer or the like may be inserted into the power module to define a high-current path, and the power module may be connected to a power lead to expand the high-current path to the outside.

A structural constraint may occur when an appropriate pattern, wire bonding, a spacer, and the like are provided in the power module. Therefore, a solution to variously change an internal structure of the power module to cope with the structural constraint caused by the pattern, the wire bonding, the spacer, and the like and improve electric power performance, cooling performance, and the like would be beneficial.

The foregoing explained as the background is intended merely to aid in the understanding of the background of the present disclosure, and is not intended to mean that the present disclosure falls within the purview of the related art that is already known to those skilled in the art.

### SUMMARY

The present disclosure is proposed to solve these problems and aims to provide a power module in which a connection structure between an upper substrate and a lower substrate is improved to improve power performance and cooling performance.

Technical problems of the present disclosure are not limited to the aforementioned technical problems, and other technical problems, which are not mentioned above, may be clearly understood by those skilled in the art from the following descriptions.

In order to achieve the above-mentioned object, a power module according to the present disclosure includes first and second substrates disposed to be spaced apart from each other and configured to define a current path using (e.g., by means of) patterns, and one or more lead frames disposed between the first substrate and the second substrate and having one side surface joined to the first substrate, and the other side surface joined to the second substrate, the lead frame being configured to support the first substrate and the second substrate and be electrically connected to the first substrate and the second substrate.

The power module may further include at least one semiconductor chip disposed in a separation space between the first substrate and the second substrate, in which the lead frame is formed to be thicker than the semiconductor chip.

The lead frames may be respectively disposed at two opposite ends of the first substrate and two opposite ends of the second substrate and joined to the first substrate and the second substrate to define a support structure between the first substrate and the second substrate.

At least one extension portion may be formed on at least one of the first and second substrates in a direction in which the substrates face each other and define the current path between the first and second substrates.

At least one extension portion may extend from the first or second substrate and be electrically connected to a semiconductor chip provided on the first or second substrate.

Each of some of the lead frames may have one end disposed between the first and second substrates and two opposite surfaces joined to the first and second substrates, and each of the remaining lead frames may be joined to any one of the first and second substrates.

The first or second substrate may further include a joining layer, and the joining layer may be made of a metallic material or made of the same material as the first or second substrate to be electrically connected to the first or second substrate.

A semiconductor chip may be joined to the joining layer, and the semiconductor chip may be electrically connected to the first or second substrate.

A support portion may protrude from the joining layer, the support portion may be provided as a plurality of support portions formed along a periphery of semiconductor chip, and the semiconductor chip may be fixed between the support portions.

The support portions may be disposed to surround a part of an edge around vertices of the semiconductor chip.

The lead frame may be formed to be relatively larger in thickness than the joining layer, the semiconductor chip, and the support portion.

A lead connection part may be electrically connected to at least any one of the first and second substrates, and the lead connection part may have a plurality of circuit lines and be electrically connected to the outside.

The lead connection part may include a film part extending along the pattern of at least one of the first and second substrates, configured to insulate the at least one pattern, and made of a flexible material, and terminal parts formed at two opposite ends of the pattern and configured to electrically connect the at least one semiconductor chip to the outside.

According to the power module provided in various embodiments of the present disclosure described above, the upper and lower substrates may be electrically connected to the lead frame, such that the wire bonding may be excluded, and the electrical connection and the heat dissipation may be performed without a spacer by improving the connection structure in the upper and lower substrates.

In addition, because the spacer for forming the large current path may be excluded, the current path may be shortened, such that the power performance may be improved, the internal space may be additionally provided (e.g., ensured), costs may be reduced, and the overall size of the power module may be reduced.

The effects capable of being obtained by the present disclosure are not limited to the aforementioned effects, and other effects, which are not mentioned above, will be clearly understood by those skilled in the art from the following description.

### BRIEF DESCRIPTION OF THE DRAWINGS

FIG. 1 is a view illustrating a power module according to an embodiment of the present disclosure.

FIG. 2 is an enlarged view of part A of the power module illustrated in FIG. 1.

FIG. 3 is an enlarged view of part B of the power module illustrated in FIG. 1.

FIG. 4 is a view illustrating a lower substrate of the power module according to the embodiment of the present disclosure.

FIG. 5 is a view illustrating a lower substrate of a power module according to another embodiment of the present disclosure.

FIG. 6 is a view illustrating the power module according to another embodiment of the present disclosure.

### DETAILED DESCRIPTION

Hereinafter, embodiments disclosed in the present specification will be described in detail with reference to the accompanying drawings. The same or similar constituent elements are assigned with the same reference numerals regardless of reference numerals, and the repetitive description thereof will be omitted.

The suffixes “module”, “unit”, “part”, and “portion” used to describe constituent elements in the following description are used together or interchangeably in order to facilitate the description, but the suffixes themselves do not have distinguishable meanings or functions.

In the description of the embodiments disclosed in the present specification, the specific descriptions of publicly known related technologies will be omitted when it is determined that the specific descriptions may obscure the subject matter of the embodiments disclosed in the present specification. In addition, it should be interpreted that the accompanying drawings are provided (e.g., only) to allow those skilled in the art to easily understand the embodiments disclosed in the present specification, and the technical spirit disclosed in the present specification is not limited by the accompanying drawings, and includes (e.g., all) alterations, equivalents, and alternatives that are included in the spirit and the technical scope of the present disclosure.

The terms including ordinal numbers such as “first,” “second,” and the like may be used to describe various constituent elements, but the constituent elements are not limited by the terms. These terms are used (e.g., only) to distinguish one constituent element from another constituent element.

When one constituent element is described as being “coupled” or “connected” to another constituent element, it should be understood that one constituent element can be coupled or connected directly to another constituent element, and an intervening constituent element can also be present between the constituent elements. When one constituent element is described as being “coupled directly to” or “connected directly to” another constituent element, it should be understood that no intervening constituent element is present between the constituent elements.

Singular expressions include plural expressions unless clearly described as having different meanings in the context.

In the present specification, it should be understood the terms “comprises,” “comprising,” “includes,” “including,” “containing,” “has,” “having” or other variations thereof are inclusive and therefore specify the presence of stated features, integers, steps, operations, elements, components, or combinations thereof, but do not preclude the presence or addition of one or more other features, integers, steps, operations, elements, components, or combinations thereof.

A power module according to an embodiment of the present disclosure provides an internal structure in which a first substrate 10 and a second substrate 20 may be connected through a lead frame 30 to define a signal path, and wire bonding and a spacer for forming a large current path may be excluded, thereby providing (e.g., ensuring) heat dissipation performance and power performance and reducing an overall size.

Hereinafter, the power module according to the exemplary embodiment of the present disclosure will be described with reference to the accompanying drawings.

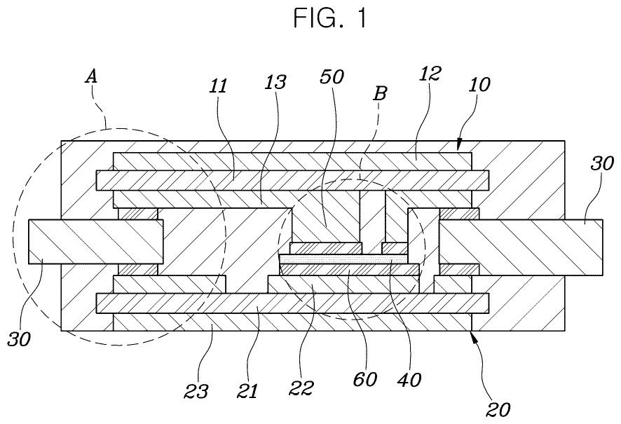

As illustrated in FIGS. 1 to 4, the power module according to the present disclosure includes the first substrate 10 and the second substrate 20 disposed to be spaced apart from each other and configured to define a current path using (e.g., by means of) patterns, and one or more lead frames 30 disposed between the first substrate 10 and the second substrate 20 and having one side surface joined to the first substrate 10, and the other side surface joined to the second substrate 20, the lead frame 30 being configured to support the first substrate 10 and the second substrate 20 and be electrically connected to the first substrate 10 and the second substrate 20.

FIG. 1 (e.g., mainly) illustrates constituent elements related to the present disclosure. An actual power module may be implemented by including more or fewer constituent elements.

The first substrate 10 may include a first insulation layer 11, and a first metal layer 12 and a second metal layer 13 respectively disposed on an upper surface and a lower surface of the first insulation layer 11 based on the first insulation layer 11.

The second substrate 20 may be disposed to be spaced apart from the first substrate 10 and include a second insulation layer 21, and a third metal layer 22 and a fourth metal layer 23 respectively disposed on an upper surface and a lower surface of the second insulation layer 21 based on the second insulation layer 21.

Therefore, the second metal layer 13 of the first substrate 10 and the third metal layer 22 of the second substrate 20 may be disposed opposite to each other, and patterns may be formed on the second metal layer 13 and the third metal layer 22 to define a current path.

At least one semiconductor chip 40 may be disposed in a separation space between the first substrate 10 and the second substrate 20.

In the embodiment according to the present disclosure, the semiconductor chip 40 may be disposed on the second substrate 20. However, the present disclosure is not limited to the configuration in which the semiconductor chip 40 is provided as a plurality of semiconductor chips 40 and disposed on the second substrate 20. The semiconductor chips 40 may be respectively disposed in the flipped states on the first substrate 10 and the second substrate 20.

The semiconductor chip 40 may be turned on or off in response to a switching signal. Whether to apply a current between upper and lower portions of the semiconductor chip 40 may be determined depending on a switching operation of the semiconductor chip 40.

In this case, the switching signal may be inputted in the form of a voltage through a signal pad provided on the semiconductor chip 40. In the case that the switching signal is inputted, at least one semiconductor chip 40 is electrically connected, such that a current may flow to a power pad provided together with a switching pad.

Meanwhile, for example, the semiconductor chip 40 may be a switching element such as an insulated gate bipolar transistor (IGBT) or a metal-oxide-semiconductor field-effect transistor (MOSFET). In addition, silicon (Si), silicon carbide (SiC), or the like may be applied as a material of the semiconductor chip 40.

The first insulation layer 11 and the second insulation layer 21 may electrically disconnect the inside and outside of the power module and may receive heat, which is generated from the semiconductor chip 40, from the second metal layer 13 and the third metal layer 22 disposed inside the power module. In addition, the first metal layer 12 may transfer again the heat received from the second metal layer 13, and the fourth metal layer 23 may transfer again the heat received from the third metal layer 22.

That is, the first metal layer 12 and the fourth metal layer 23 may serve to dissipate the received heat while exchanging heat with the outside and cool the power module. Therefore, the first metal layer 12 and the fourth metal layer 23 may reduce an operating temperature of the power module, thereby allowing the power module to (e.g., stably) operate.

In addition, a cooling channel (not illustrated) may be additionally provided outside the first metal layer 12 or the fourth metal layer 23 to improve the performance in cooling the power module. For example, the cooling channel may be applied in an air-cooled or water-cooled manner and improve the performance in cooling the power module by improving the cooling efficiency with (e.g., by means of) a refrigerant.

Meanwhile, for example, the first to fourth metal layers 12, 13, 22, and 23 may be made of copper (Cu), and the first insulation layer 11 and the second insulation layer 21 may be made of ceramic. In this case, the upper substrate and the lower substrate may each be implemented as active metal brazed (AMB) substrate or a direct bonded copper (DBC) substrate.

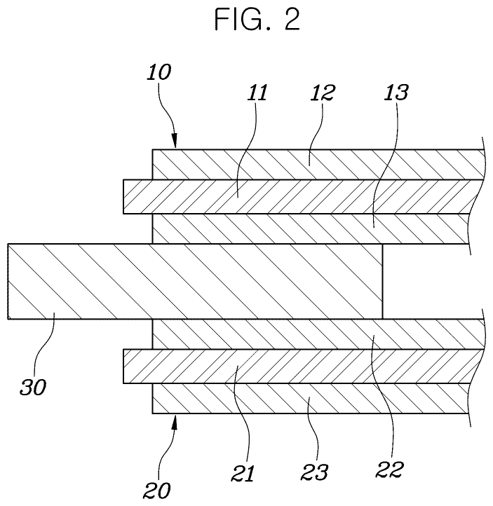

Meanwhile, as illustrated in FIGS. 1 and 2, the lead frame 30 may be disposed between the first substrate 10 and the second substrate 20. The lead frame 30 may be provided as a plurality of lead frames 30. One side surface of the lead frame 30 may be joined to the first substrate 10, and the other side surface of the lead frame 30 may be joined to the second substrate 20, such that the lead frame 30 supports the first substrate 10 and the second substrate 20 and is electrically connected to the first substrate 10 and the second substrate 20.

The lead frame 30 may be connected to the first substrate 10 and the second substrate 20 and connect the semiconductor chip 40 to the outside of the power module, such that wire bonding may be excluded, and a minimum height constraint caused by the application of wire bonding may be eliminated (e.g., or reduced). Therefore, a spacing distance between the first substrate 10 and the second substrate 20 may be shortened, and a current path may be shortened, which may mitigate deterioration in power performance caused by parasitic components or the like.

In particular, the lead frame 30 may define a support structure between the first substrate 10 and the second substrate 20 in the state in which one side surface of the lead frame 30 adjoins the first substrate 10 and the other side surface of the lead frame 30 adjoins the second substrate 20.

Therefore, the power module according to the present disclosure may minimize or exclude the application of a spacer that can be configured to support the first substrate 10 and the second substrate 20 and implement an electrical connection, thereby reducing the overall size.

In addition, among the spacer, a chip spacer serves to allow a large current to flow through the semiconductor chip 40, and costs increase because a composite material, such as Cu—Mo or Al—SiC, can (e.g., needs to) be applied to the chip spacer. Therefore, costs may be reduced by excluding the spacer.

In addition, because the lead frame 30 electrically connects the first substrate 10 and the second substrate 20, a circuit pattern may be simplified even though the circuit pattern for each of the substrates is complicated.

Meanwhile, the lead frame 30 may be formed to be larger in thickness than the semiconductor chip 40. In this case, the thickness may be a (e.g., larger) length in an upward/downward direction in FIG. 1.

Because the lead frame 30 is formed to be larger in thickness than the semiconductor chip 40 as described above, the lead frame 30 may be configured to be connected to the first substrate 10 and the second substrate 20, and the semiconductor chip 40 may be configured to adjoin (e.g., only) any one of the first substrate 10 and the second substrate 20.

Therefore, the lead frame 30 may define the support structure between the first substrate 10 and the second substrate 20 while electrically connecting the first substrate 10 and the second substrate 20, such that damage to the semiconductor chip 40 may be (e.g., substantially) prevented. Further, the lead frame 30 may be electrically connected to the first substrate 10 and the second substrate 20 and define the current path using (e.g., by means of) the circuit pattern of each of the substrates.

Meanwhile, the lead frames 30 may be respectively disposed at two opposite ends of the first substrate 10 and two opposite ends of the second substrate 20 and joined to the first substrate 10 and the second substrate 20, thereby implementing the support structure between the first substrate 10 and the second substrate 20.

As can be seen in FIG. 1, the lead frames 30 may be respectively disposed at the two opposite ends of the first substrate 10 and the two opposite ends of the second substrate 20 and support the two opposite ends of the first substrate 10 and the two opposite ends of the second substrate 20, such that the first substrate 10 and the second substrate 20 may be electrically connected and constitute the (e.g., stable) support structure.

One side surface and the other side surface of the lead frame 30 may be joined to the first substrate 10 and the second substrate 20 by soldering, sintering, or the like, and the lead frame 30 may be joined to the first substrate 10 and the second substrate 20 and (e.g., substantially) fixed in position, such that the electrically connected state and the (e.g., stable) support structure may be (e.g., substantially) maintained.

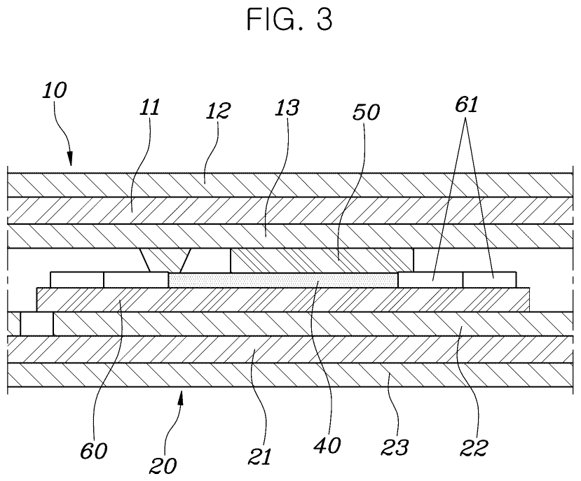

Meanwhile, as illustrated in FIG. 3, at least one extension portion 50 may be formed on at least one of the first substrate 10 and the second substrate 20 in a direction in which the substrates face each other, thereby defining the current path between the first substrate 10 and the second substrate 20.

The extension portion 50 may be made of copper and a copper alloy and configured to electrically connect the first substrate 10 and the second substrate 20 and transfer heat.

The extension portion 50 may be integrated with any one of the first substrate 10 and the second substrate 20. The extension portion 50 may be manufactured separately from any one of the first substrate 10 and the second substrate 20 and joined to any one of the first substrate 10 and the second substrate 20 by soldering, sintering, or the like.

In this case, at least one extension portion 50 may extend from the first substrate 10 or the second substrate 20 and be electrically connected to the semiconductor chip 40 provided on the first substrate 10 or the second substrate 20.

Therefore, because the extension portion 50 extends from the first substrate 10 or the second substrate 20, in the direction in which the substrates face each other, and the extension portion 50 is electrically connected to the opposite substrate, the current paths of the first and second substrates 10 and 20 may be formed even though the plurality of semiconductor chips 40 are applied in the power module or the circuit pattern is complicated.

Meanwhile, each of some of the lead frames 30 may have one end disposed between the first substrate 10 and the second substrate 20 and two opposite surfaces joined to the first substrate 10 and the second substrate 20, and each of the remaining lead frames 30 may be joined to any one of the first substrate 10 and the second substrate 20.

That is, the lead frame 30 may define a signal connection path or a (e.g., large) current path between the inside and outside of the power module and be expressed as a signal lead or a power lead depending on the defined path.

The lead frame 30 may be provided as a plurality of lead frames 30 depending on the patterns of the first and second substrates 10 and 20. Some of the lead frames 30 may be joined to the first substrate 10 and the second substrate 20 and define the support structure, and the remaining lead frames 30 may be joined (e.g., only) to the first substrate 10 or the second substrate 20 depending on the circuit pattern.

In the present disclosure, because (e.g., all) the lead frames 30 can be joined to the first substrate 10 and the second substrate 20 and define the (e.g, stable) support structure, the circuit patterns of the first and second substrates 10 and 20 may be formed in consideration of the above-mentioned configuration.

Meanwhile, the first substrate 10 or the second substrate 20 may further include a joining layer 60, and the joining layer 60 may be made of a metallic material or made of the same material as the first substrate 10 or the second substrate 20 so as to be electrically connected to the first substrate 10 or the second substrate 20.

The joining layer 60 may be configured in a shape in which metal layers, which constitute the first substrate 10 or the second substrate 20, are stacked and extend. That is, the joining layer 60 may be metal layers of the first and second substrates 10 and 20. The metal layers are stacked in the direction in which the first substrate 10 and the second substrate 20 face each other, such that the first substrate 10 and the second substrate 20 may be electrically connected and transfer heat to each other.

The semiconductor chip 40 may be joined to the joining layer 60, such that the semiconductor chip 40 may be electrically connected to the first substrate 10 or the second substrate 20. As described above, the semiconductor chip 40 may be seated and (e.g., substantially) fixed onto a portion of the first or second substrate 10 or 20 on which the joining layer 60 is formed. Therefore, the joining layer 60 may be formed in a shape on which the semiconductor chip 40 may be stabilized and seated, and the joining layer 60 may be electrically connected through the signal pad.

Further, support portions 61 may protrude from the joining layer 60. The support portions 61 may be provided as a plurality of support portions 61 formed along a periphery of the semiconductor chip 40, and the semiconductor chip 40 may be (e.g., substantially) fixed between the support portions 61.

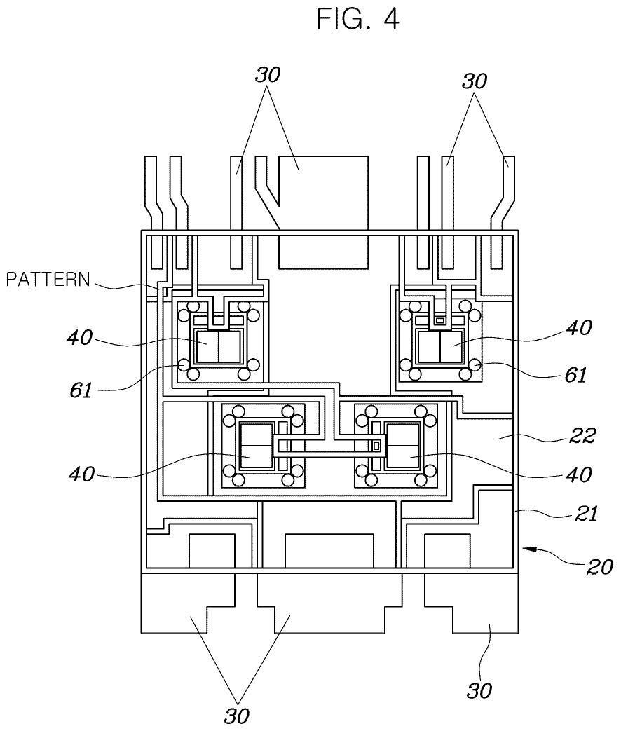

As illustrated in FIG. 4, the support portion 61 may be made of the same material as the joining layer 60 and made of a material identical to the metal layer that constitutes the first substrate 10 or the second substrate 20.

Therefore, the support portion 61 may be configured in a shape in which metal layers are stacked and extend on the joining layer 60.

In particular, because the plurality of support portions 61 are formed along the periphery of the semiconductor chip 40, the semiconductor chip 40 may be (e.g., substantially) fixed by the plurality of support portions 61. That is, the support portion 61 may be formed in a shape extending and protruding from the joining layer 60. The support portions 61 are disposed to be spaced apart from one another along a rim of the semiconductor chip 40 and surround the rim of the semiconductor chip 40.

The support portions 61 may be disposed to surround a part of an edge around vertices of the semiconductor chip 40.

Therefore, the semiconductor chip 40 may be surrounded by the support portions 61, a position of the semiconductor chip 40 may be (e.g., substantially) stably fixed to the first substrate 10 or the second substrate 20, and the support portions 61 are disposed at the edge that is a portion of the semiconductor chip 40 where rigidity is provided (e.g., relatively ensured), such that damage to the semiconductor chip 40 may be prevented.

The support portion 61 may be configured on the joining layer 60 by soldering, sintering, or the like, and various embodiments may be applied.

Meanwhile, the lead frame 30 may be formed to be relatively larger in thickness than the joining layer 60, the semiconductor chip 40, and the support portion 61.

Because the lead frame 30 is formed to be larger in thickness than the joining layer 60, the semiconductor chip 40, and the support portion 61 as described above, the lead frame 30 may be disposed between the first substrate 10 and the second substrate 20 and connected to the first substrate 10 and the second substrate 20, and the joining layer 60, the semiconductor chip 40, and the support portion 61 may be configured to adjoin (e.g., only) any one of the first substrate 10 and the second substrate 20.

Therefore, the lead frame 30 may define the support structure between the first substrate 10 and the second substrate 20 while electrically connecting the first substrate 10 and the second substrate 20 without interfering with the joining layer 60, the semiconductor chip 40, and the support portion 61.

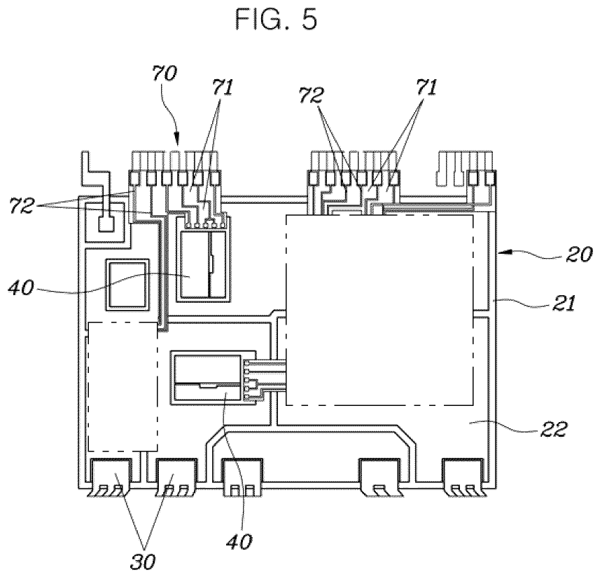

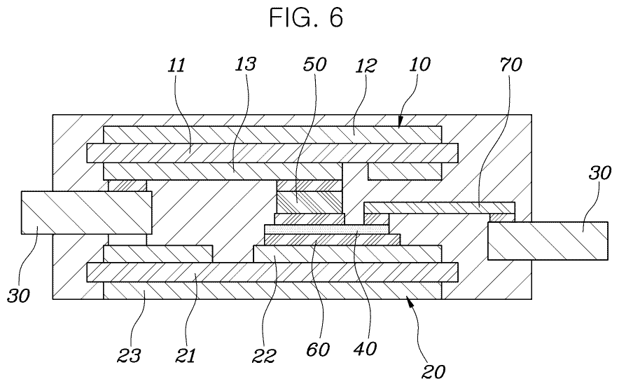

Meanwhile, in another embodiment of the present disclosure of FIGS. 5 and 6, a lead connection part 70 may be electrically connected to at least any one of the first substrate 10 and the second substrate 20, and the lead connection part 70 may have a plurality of circuit lines and be electrically connected to the outside.

One end of the lead connection part 70 may be electrically connected to the signal pad of any one of the semiconductor chips 40, and the other end of the lead connection part 70 may include at least one of the plurality of circuit lines extending outward from the first substrate 10 and the second substrate 20 and be electrically connected to the outside.

The lead connection part 70 may be disposed at a side of the first or second substrate 10 or 20 opposite to the lead frame 30.

The lead connection part 70 may include a film part 71 extending along the pattern of at least one of the first substrate 10 and the second substrate 20, configured to insulate the at least one pattern, and made of a flexible material, and terminal parts 72 formed at two opposite ends of the pattern and configured to electrically connect the at least one semiconductor chip 40 to the outside. That is, the lead connection part 70 may be implemented as a flexible printed circuit board (FPCB).

Meanwhile, in the first substrate 10 and the second substrate 20 of the power module according to another embodiment, the lead frame 30 defines the support structure on the portion where the lead frame 30 is provided, and the electrical connection is performed on the portion where the lead connection part 70 is provided, such that the extension portion 50 or a spacer may be applied to define the electrical connection and the mutual support structure between the first substrate 10 and the second substrate 20.

According to the power module according to various embodiments of the present disclosure described above, the upper and lower substrates may be electrically connected to the lead frame 30, such that the wire bonding may be excluded, and the electrical connection and the heat dissipation may be performed without a spacer by improving the connection structure in the upper and lower substrates.

In addition, because the spacer for forming the (e.g., large) current path may be excluded, the current path may be shortened, such that the power performance may be improved, the internal space may be additionally provided (e.g., ensured), costs may be reduced, and the overall size of the power module may be reduced.

While the specific embodiments of the present disclosure have been illustrated and described, the present disclosure may be variously modified and changed without departing from the technical spirit of the present disclosure defined in the appended claims.

What is claimed is:

1. A power module comprising:
first and second substrates disposed to be spaced apart from each other and configured to define a current path using patterns; and
one or more lead frames disposed between the first substrate and the second substrate and having one side surface joined to the first substrate, and the other side surface joined to the second substrate, the lead frame being configured to support the first substrate and the second substrate and be electrically connected to the first substrate and the second substrate.

2. The power module of claim 1, further comprising:
at least one semiconductor chip disposed in a separation space between the first substrate and the second substrate,
wherein at least one of the lead frames is formed to be thicker than the semiconductor chip.

3. The power module of claim 1, wherein the lead frames are respectively disposed at two opposite ends of the first substrate and two opposite ends of the second substrate and joined to the first substrate and the second substrate to define a support structure between the first substrate and the second substrate.

4. The power module of claim 1, wherein at least one extension portion is formed on at least one of the first and second substrates in a direction in which the first and second substrates face each other and defines the current path between the first and second substrates.

5. The power module of claim 4, wherein at least one extension portion extends from the first or second substrate and is electrically connected to a semiconductor chip provided on the first or second substrate.

6. The power module of claim 1, wherein each of some of the lead frames has one end disposed between the first and second substrates and two opposite surfaces joined to the first and second substrates, and each of the remaining lead frames is joined to any one of the first and second substrates.

7. The power module of claim 1, wherein the first or second substrate further comprises a joining layer, and the joining layer is made of a metallic material or made of the same material as the first or second substrate to be electrically connected to the first or second substrate.

8. The power module of claim 7, wherein a semiconductor chip is joined to the joining layer, and the semiconductor chip is electrically connected to the first or second substrate.

9. The power module of claim 8, wherein a support portion protrudes from the joining layer, the support portion is provided as a plurality of support portions formed along a periphery of semiconductor chip, and the semiconductor chip is fixed between the support portions.

10. The power module of claim 9, wherein at least one of the support portions is disposed to surround a part of an edge around vertices of the semiconductor chip.

11. The power module of claim 9, wherein at least one of the lead frames is formed to be relatively larger in thickness than the joining layer, the semiconductor chip, and the support portion.

12. The power module of claim 1, wherein a lead connection part is electrically connected to at least any one of the first and second substrates, and the lead connection part has a plurality of circuit lines and is electrically connected to the outside.

13. The power module of claim 12, wherein the lead connection part comprises:
a film part extending along at least one of the patterns of at least one of the first and second substrates, configured to insulate the at least one pattern, and made of a flexible material; and
terminal parts formed at two opposite ends of the pattern and configured to electrically connect at least one semiconductor chip to the outside.
